(19) United States
(12) Patent Application Publication
(10) Pub. No.: US 2017/0250370 A1
(43) Pub. Date: Aug. 31, 2017

(54) METHODS FOR INTEGRATION OF ORGANIC AND INORGANIC MATERIALS FOR OLED ENCAPSULATING STRUCTURES

(71) Applicant: Applied Materials, Inc., Santa Clara, CA (US)

(72) Inventors: Jrjyan Jerry CHEN, Campbell, CA (US); Soo Young CHOI, Fremont, CA (US); Helinda NOMINANDA, Santa Clara, CA (US); Wen-Hao WU, San Jose, CA (US)

(21) Appl. No.: 15/055,269

(22) Filed: Feb. 26, 2016

(51) Int. Cl. H01L 51/52; H01L 51/00; H01L 51/56

(52) U.S. Cl. CPC H01L 51/5253; H01L 51/56; H01L 51/0043; H01L 51/0038; H01L 51/0041; H01L 51/004; H01L 2251/301; H01L 2251/303

(57) ABSTRACT

Embodiments of the disclosure provide interface integration and adhesion improvement methods used on a transparent substrate for OLED or thin film transistor applications. In one embodiment, a method of enhancing interface adhesion and integration in a film structure disposed on a substrate includes performing a plasma treatment process on an inorganic layer disposed on a substrate in a processing chamber to form a treated layer on the substrate, wherein the substrate includes an OLED structure, controlling a substrate temperature less than about 100 degrees Celsius, and forming an organic layer on the treated layer. Furthermore, an encapsulating structure for OLED applications includes an inorganic layer formed on an OLED structure on a substrate, an electron beam treated layer formed on the inorganic layer, and an organic layer formed on the electron beam treated layer.

### BACKGROUND OF THE DISCLOSURE

### Field of the Disclosure

Embodiments of the present disclosure generally relate to methods for improving interface adhesion and integration. More particularly, embodiments of the present disclosure relate to interface management methods performed on a surface of a substrate used in thin-film transistor or OLED applications.

### Description of the Related Art

Organic light emitting diode displays (OLED) have gained significant interest recently in display applications in view of their faster response times, larger viewing angles, higher contrast, lighter weight, lower power and amenability to flexible substrates. Generally, a conventional OLED is enabled by using one or more layers of organic materials sandwiched between two electrodes for emitting light. The one or more layers of organic materials include one layer capable of monopolar (hole) transport and another layer for electroluminescence and thus lower the required operating voltage for OLED display.

In addition to organic materials used in OLED, many polymer materials are also developed for small molecule, flexible organic light emitting diode (FOLED) and polymer light emitting diode (PLED) displays. Many of these organic and polymer materials are flexible for the fabrication of complex, multi-layer devices on a range of substrates, making them ideal for various transparent multi-color display applications, such as thin flat panel display (FPD), electrically pumped organic laser, and organic optical amplifier.

Over the years, layers in display devices have evolved into multiple layers with each layer serving different function. FIG. 1 depicts an example of an OLED device structure 100 built on a substrate 102. The OLED device structure 100 includes an anode layer 104 deposited on the substrate 102. The substrate 102 may be made of glass or plastic, such as polyethyleneterephthalate (PET) or polyethyleneterephthalate (PEN). An example of the anode layer 104 is an indium-tin-oxide (ITO).

Multiple layers of organic or polymer materials 106 may be deposited on the anode layer 104. Multiple layers of organic or polymer materials 106 may generally include a hole-transport layer and an emissive layer. Different organic materials may be used to fabricate the hole-transport layer and the emissive layer. Suitable examples of the hole-transport layer may be fabricated from diamine, such as a naphthyl-substituted benzidine (NPB) derivative, or N,N′-diphenyl-N,N′-bis(3-methylphenyl)-(1,1′-biphenyl)-4,4′-diamine (TPD). Additionally, suitable examples of the emissive layer may be fabricated from 8-hydroxyquinoline aluminum (Alq₃). Subsequently, an electrode layer 108 or called cathode layer may be formed on the organic or polymer materials 106 to complete the device structure 100. The electrode layer 108 can be a metal, a mixture of metals or an alloy of metals. An example of the top electrode material is an alloy of magnesium (Mg), silver (Ag) and aluminum (Al) in the thickness range of about 1000 Å to about 3000 Å. The structure of the organic or polymer materials 106 and the choice of anode and cathode layers 104, 108 are designed to maximize the recombination process in the emissive layer, thus maximizing the light output from the OLED devices.

After the device structure 100 is formed on the substrate 102, a first inorganic layer 111 followed by an encapsulating organic layer 110 formed thereon. Subsequently, a second encapsulating inorganic layer 112 formed thereon. Additional passivation layers 116, 118, including organic or inorganic materials, may be formed on the encapsulating inorganic layer 112 as needed to provide sealing of the device structure 100 from moisture or air exposure. However, different materials, especially organic and inorganic materials, often have different film properties, thereby resulting in poor surface adhesion at the interface where the organic and the inorganic layers are in contact with. For example, poor adhesion is often present at an interface 113 between the first inorganic layer 111 and the encapsulating organic layer 110, or an interface 114 formed between the first encapsulating organic layer 110 and the second encapsulating inorganic layer 112. Poor interface adhesion often allows film peeling or particle generation, thereby adversely contaminating the device structure 100 and eventually leading to device failure. Additionally, poor adhesion at the interfaces 113, 114 may also increase the likelihood of film cracking, thereby allowing the moisture or air to sneak into the device structure 100, thereby deteriorating the device electrical performance.

Thus, there is a need for methods to form an interface between an organic and an inorganic layer with good adhesion while maintaining good passivation capability to protect the device structure from moisture.

### SUMMARY OF THE DISCLOSURE

Embodiments of the disclosure provide interface integration and adhesion improvement methods used on a transparent substrate for OLED or thin film transistor applications. In one embodiment, a method of enhancing interface adhesion and integration in a film structure disposed on a substrate includes performing a plasma treatment process on an inorganic layer disposed on a substrate in a processing chamber to form a treated layer on the substrate, wherein the substrate includes an OLED structure, controlling a substrate temperature less than about 100 degrees Celsius, and forming an organic layer on the treated layer.

In another embodiment, an encapsulating structure for OLED applications includes an inorganic layer formed on an OLED structure on a substrate, an electron beam treated layer formed on the inorganic layer, and an organic layer formed on the electron beam treated layer.

In yet another embodiment, an encapsulating structure for OLED applications includes a first inorganic layer disposed in direct contact with an OLED structure, a second inorganic layer disposed on the first inorganic layer, an electron beam treated layer formed on the inorganic layer, and an organic layer formed on the electron beam treated layer.

### BRIEF DESCRIPTION OF THE DRAWINGS

So that the manner in which the above recited features of the present disclosure are attained and can be understood in detail, a more particular description of the disclosure, briefly summarized above, may be had by reference to the embodiments thereof which are illustrated in the appended drawings.

FIG. 1 depicts a schematic side-view of a OLED structure;

FIG. 2 depicts a cross-sectional view of an apparatus suitable for depositing a buffer layer according to one embodiment of the disclosure;

FIG. 3 depicts an enlarged view of a portion of the electron beam apparatus depicted in FIG. 1;

FIG. 4 depicts a schematic illustration of a deposition apparatus with an integrated electron beam source that can be used to practice embodiments of

FIG. 5 depicts a process flow diagram for performing an interface adhesion enhancement process on a substrate in accordance with one embodiment of the present disclosure; and

FIGS. 6A-6F depict a sequence of fabrication stages of the interface integration and adhesion enhancement process in accordance with one embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this disclosure and are therefore not to be considered limiting of its scope, for the disclosure may admit to other equally effective embodiments.

### DETAILED DESCRIPTION

Embodiments of the present invention include methods for improving film structure integration and interface adhesion between an organic and an inorganic layer. In some embodiment, the disclosure may be advantageously used in OLED applications or thin film transistor applications. In one embodiment, the film structure integration and interface adhesion are improved by e-beam treatment on a first layer (e.g., an organic layer or an inorganic layer) prior to a second layer (e.g., an inorganic layer or an organic layer) formed thereon at the interface. As the e-beam treatment process alters at least some of surface properties, e.g., wetability or surface roughness, atoms from the subsequent deposited layer to be adhered more securely on the interface between the organic and the inorganic layer as compared to conventional deposition techniques.

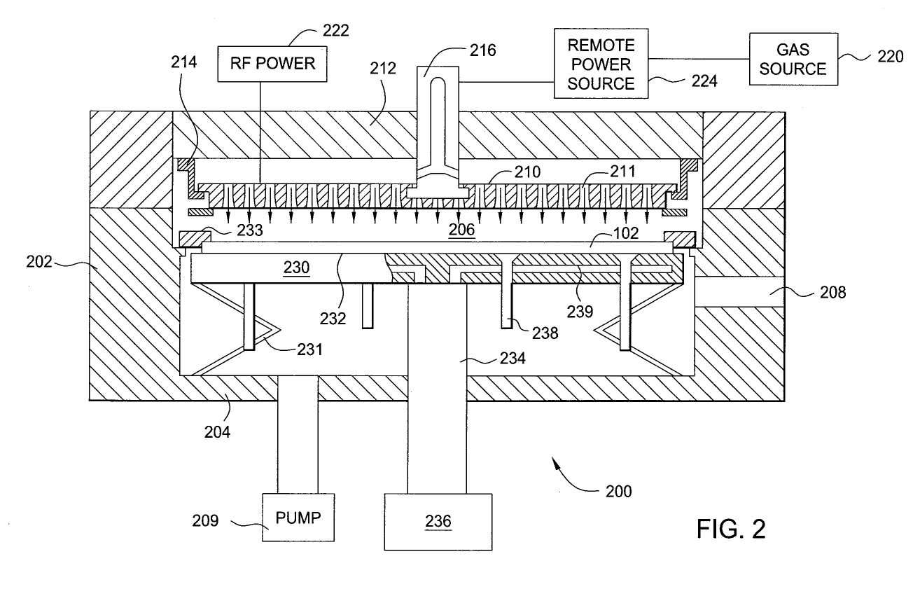

FIG. 2 is a schematic cross-section view of one embodiment of a plasma enhanced chemical vapor deposition (PECVD) chamber 200 in which an inorganic or organic layer deposition process may be performed therein. It is noted that FIG. 2 is just an exemplary apparatus that may be used to perform the inorganic or organic layer deposition process on a substrate. One suitable plasma enhanced chemical vapor deposition chamber is available from Applied Materials, Inc., located in Santa Clara, Calif. It is contemplated that other deposition chambers, including those from other manufacturers, may be utilized to practice the present disclosure.

The PECVD chamber 200 generally includes walls 202, a bottom 204, and a showerhead 210 which define a process volume 206. The process volume 206 is accessed through a sealable slit valve 208 formed through the walls 202 such that the substrate, may be transferred in and out of the PECVD chamber 200. A substrate support 230 is disposed in the process volume 206 and includes a substrate receiving surface 232 for supporting a substrate 102 and stem 234 coupled to a lift system 236 to raise and lower the substrate support 230. A shadow ring 233 may be optionally placed over periphery of the substrate 102. Lift pins 238 are moveably disposed through the substrate support 230 to move the substrate 102 to and from the substrate receiving surface 232. The substrate support 230 may also include heating and/or cooling elements 239 to maintain the substrate support 230 and substrate 102 positioned thereon at a desired temperature. The substrate support 230 may also include grounding straps 231 to provide RF grounding at the periphery of the substrate support 230.

The showerhead 210 is coupled to a backing plate 212 at its periphery by a suspension 214. The showerhead 210 may also be coupled to the backing plate 212 by one or more center supports 216 to help prevent sag and/or control the straightness/curvature of the showerhead 210. A gas source 220 is coupled to the backing plate 212 to provide gas through the backing plate 212 and the showerhead 210 to the substrate receiving surface 232. A vacuum pump 209 is coupled to the PECVD chamber 200 to control the pressure within the process volume 206. An RF power source 222 is coupled to the backing plate 212 and/or to the showerhead 210 to provide RF power to the showerhead 210 to generate an electric field between the showerhead 210 and the substrate support 230 so that a plasma may be formed from the gases present between the showerhead 210 and the substrate support 230. Various RF frequencies may be used, such as a frequency between about 0.3 MHz and about 200 MHz. In one embodiment the RF power source 222 provides power to the showerhead 210 at a frequency of 13.56 MHz.

A remote plasma source 224, such as an inductively coupled remote plasma source, may also be coupled between the gas source 220 and the backing plate 212. Between processing substrates, a cleaning gas may be provided to the remote plasma source 224 and excited to form a remote plasma from which dissociated cleaning gas species are generated and provided to clean chamber components. The cleaning gas may be further excited by the RF power source 222 provided to the showerhead 210 to reduce recombination of the dissociated cleaning gas species. Suitable cleaning gases include but are not limited to NF₃, E₂, and SF₆.

In one embodiment, the heating and/or cooling elements 239 may be utilized to maintain the temperature of the substrate support 230 and substrate 102 thereon during deposition less than about 400° C. or less. In one embodiment, the heating and/or cooling elements 239 may used to control the substrate temperature less than 100 degrees Celsius, such as between 20 degree Celsius and about 90 degrees Celsius.

The spacing during deposition between a top surface of the substrate 102 disposed on the substrate receiving surface 232 and the showerhead 210 may be between 400 mil and about 1,200 mil, for example between 400 mil and about 800 mil.

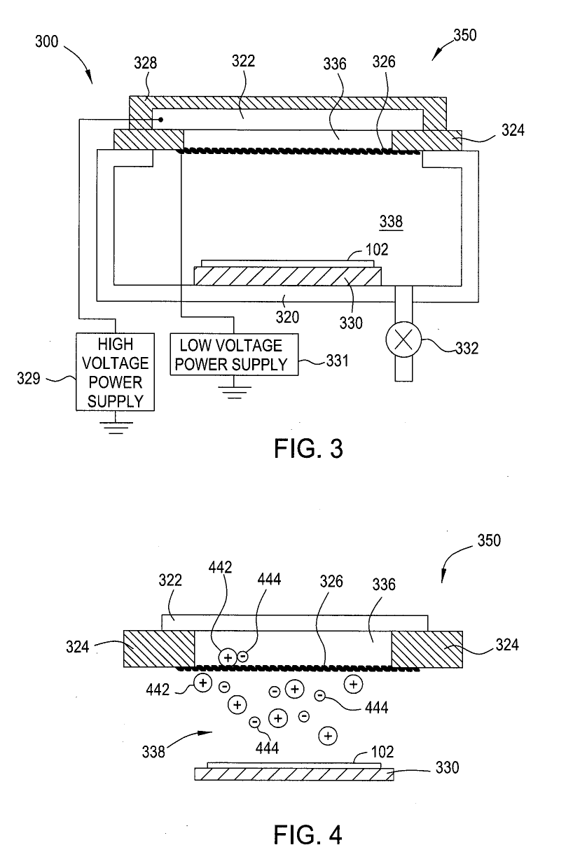

FIG. 3 illustrates an electron beam chamber 300 that may be utilized to treat a film layer, such as an organic or inorganic layer, according to one embodiment of the disclosure. An example of such an electron beam apparatus is EBK™ chamber, available from Applied Materials, Inc., of Santa Clara, Calif. The electron beam chamber 300 includes a substrate support 330 disposed in the electron beam chamber 300 having an electron beam generating system 350 disposed above the substrate support 330. The electron beam generating system 350 includes a large-area cathode 322, a field-free region 338, and a grid anode 326 positioned between the substrate support 330 and the large-area cathode 322. A high voltage insulator 324 is disposed in the electron beam generating system 350 isolating the grid anode 326 from the large-area cathode 322. A cathode cover insulator 328 is located outside the electron beam chamber 300. A variable leak valve 332 is utilized to control the pressure inside the electron beam chamber 300. A variable high voltage power supply 329 is connected to the large-area cathode 322, and a variable low voltage power supply 331 is connected to the grid anode 326.

In operation, the substrate (not shown) to be exposed with the electron beam generated from the electron beam generating system 350 is placed on the substrate support 330. The electron beam chamber 300 is pumped from atmospheric pressure to a pressure in the range of about 1 mTorr to about 200 mTorr. The exact pressure is controlled by the variable leak valve 332, which is capable of controlling pressure to about 0.1 mTorr. The electron beam is generally generated at a sufficiently high voltage, which is applied to the large-area cathode 322 by the high voltage power supply 329. The voltage may range from about −500 volts to about 30,000 volts or higher. The variable voltage power supply 331 applies a voltage to the grid anode 326 that is positive relative to the voltage applied to the large-area cathode 322. This voltage is used to control electron emission from the large-area cathode 322.

To initiate electron emission, the gas in the space between the large-area cathode 322 and the substrate support 330 is ionized, which may occur as a result of naturally occurring gamma rays. Electron emission may also be artificially initiated inside the electron beam chamber 300 by a high voltage spark gap. Once this initial ionization takes place, positive ions 442 (shown in FIG. 4) are attracted to the grid anode 326 by a slightly negative voltage, i.e., on the order of about 0 to about −200 volts, applied to the grid anode 326. These positive ions 442 pass into the accelerating field region 336, disposed between the large-area cathode 322 and the grid anode 326, and are accelerated towards the large-area cathode 322 as a result of the high voltage applied to the large-area cathode 322. Upon striking the large-area cathode 322, these high-energy ions produce secondary electrons 444, which are accelerated back toward the grid anode 326. Some of these electrons, which travel generally perpendicular to the cathode surface, strike the grid anode 326, but many pass through the anode 326 and travel to the substrate support 330. The grid anode 326 is positioned at a distance less than the mean free path of the electrons emitted by the large-area cathode 322, e.g., the grid anode 326 is positioned less than about 4 mm from the large-area cathode 322. Due to the short distance between the grid anode 326 and the large-area cathode 322, no, or minimal if any, ionization takes place in the accelerating field region 336 between the grid anode 326 and the large-area cathode 322.

In a gas discharge device, the electrons would create further positive ions in the accelerating field region, which would be attracted to the large-area cathode 322, creating even more electron emission. The discharge could easily avalanche into an unstable high voltage breakdown. However, in accordance with an embodiment of the invention, the ions 442 created outside the grid anode 326 may be controlled (repelled or attracted) by the voltage applied to the grid anode 326. In other words, the electron emission may be continuously controlled by varying the voltage on the grid anode 326. Alternatively, the electron emission may be controlled by the variable leak valve 332, which is configured to raise or lower the number of molecules in the ionization region between the substrate support 330 and the large-area cathode 322. The electron emission may be entirely turned off by applying a positive voltage to the grid anode 326, i.e., when the grid anode voltage exceeds the energy of any of the positive ion species created in the space between the grid anode 326 and substrate support 330.

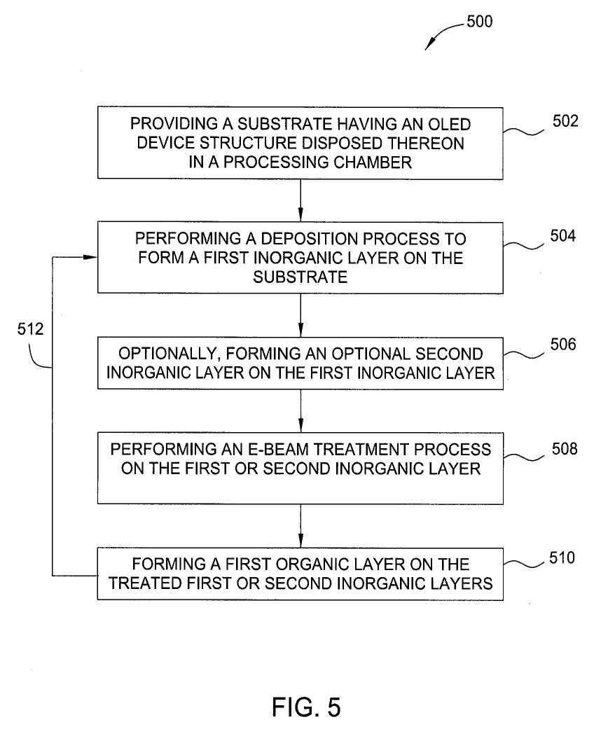

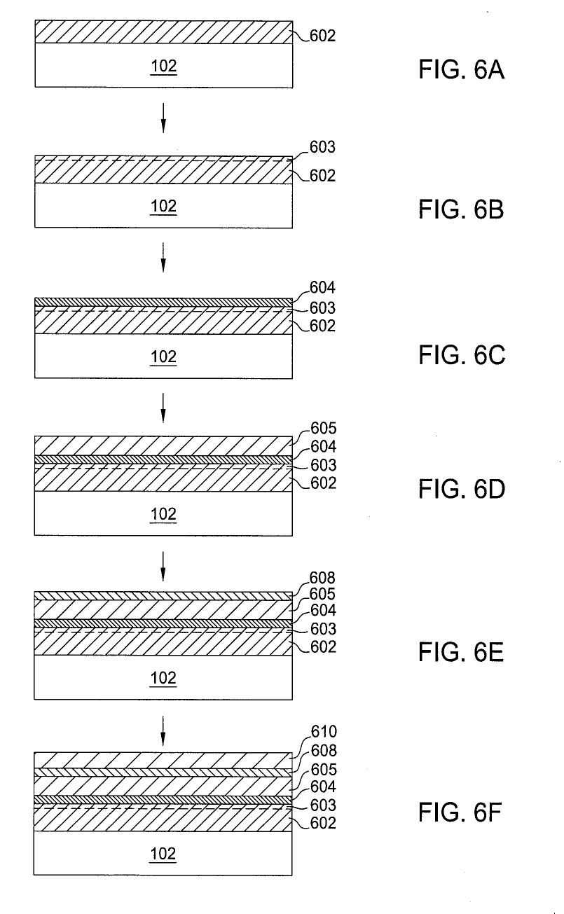

FIG. 5 is a flow diagram of one embodiment of an film stack integration and interface adhesion enhancement process 500 performed on a surface of a substrate. The process 500 may be performed in a processing chamber, such as the PECVD chamber 200 depicted in FIG. 2 and an electron beam generating system 350 depicted in FIGS. 3-4. FIGS. 6A-6F depict a sequence of fabrication stages of performing film stack integration and interface adhesion enhancement process on a substrate according to the process 500 depicted in FIG. 5. The following description of the process 500 is made with simultaneous reference to FIGS. 6A-6F.

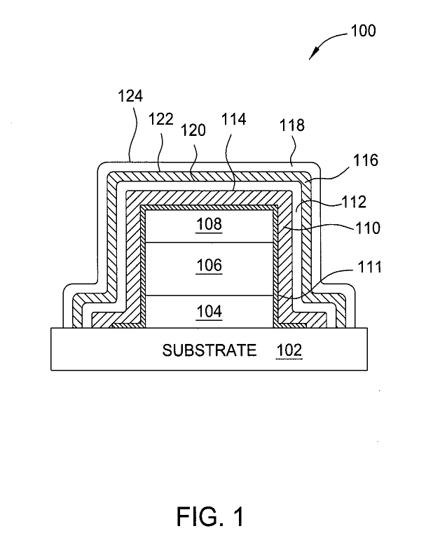

The process 500 begins at operation 502 by transferring (i.e., providing) the substrate 102, as shown in FIG. 6A, to a processing chamber, such as the PECVD chamber 200 depicted in FIG. 2 or other suitable chamber. In the embodiment depicted in FIG. 6A, the substrate 102 may be thin sheet of metal, plastic, organic materials, glass, quartz, or polymer, or other suitable material. In one embodiment, the substrate 102 may have a top surface area greater than about 1 square meters, such as greater than about 6 square meters. The substrate 102 may be configured to form OLED or thin film transistor devices, or other types of display applications as needed. In another embodiment, the substrate 102 may be configured to have OLED or thin film transistor devices, or other types of display applications having an inorganic layer formed thereon as needed. In one embodiment, the substrate 102 may include OLED device structure, such as the OLED device structure 100 depicted in FIG. 1, disposed thereon.

At operation 504, a deposition process may be performed to form a first inorganic layer 602, as shown in FIG. 6A, on the substrate 102. The first inorganic layer 602 may be similar or the same as the inorganic layer 111 formed on the OLED device structure 100 depicted in FIG. 1. In one example, the first inorganic layer 602 may be a silicon containing layer. For example, the first inorganic layer 602 is a silicon nitride or silicon oxygen layer. In one particular example, the first inorganic layer 602 may be a silicon nitride layer.

In one embodiment, the deposition process for forming the first inorganic layer 602 at operation 504 may be performed by supplying a gas mixture into the PECVD chamber 200. In one example, the gas mixture may include at least a silicon containing and a nitrogen containing gas. Suitable examples of the silicon containing gas include SiH₄, Si₂H₆, SiCl₄ and the like. Suitable examples of the nitrogen containing gas include N₂, NH₃, N₂O, NO₂, combinations thereof and the like. An inert gas may be optionally supplied in the gas mixture to assist forming the first inorganic layer 602. In this particular embodiment, the SiH₄ gas supplied in the gas mixture is controlled at between about 4.0 sccm/L and about 15 sccm/L. N₂ gas is supplied to the gas mixture between about 44 sccm/L and about 66 sccm/L. NH₃ gas is supplied to the gas mixture between about 19 sccm/L and about 40 sccm/L. The N₂ gas and NH₃ gas supplied in the gas mixture may be controlled at a flow ratio from about 1:1 to about 1:10, such as between about 1:2 and about 1:5, for example between about 1:1.5 and about 1:3.

Several process parameters may be controlled while performing the inorganic layer deposition process. A RF power supplied to do the deposition process may be controlled at between about 0 milliWatts/cm² and about 1500 milliWatts/cm², such as about 1000 milliWatts/cm², may be provided to the 600 milliWatts/cm² for deposition process. The RF power is controlled at a high range greater than 500 milliWatts/cm². The substrate temperature may be controlled less than 100 degrees Celsius. As the substrate 102 includes organic materials disposed thereon, a low temperature deposition process, such as less than 100 degrees Celsius, is utilized so as to deposit the buffer layer 404 with desired properties while maintaining the film properties of the organic layers formed on the substrate 102. In one embodiment, the substrate temperature is controlled at between about 70 degrees Celsius and about 90 degrees Celsius. The spacing may be controlled between about 800 mils and about 1000 mils. The process pressure may be controlled at between about 1 Torr and about 2 Torr. The process time may be controlled at a range when a desired thickness of the first inorganic layer 602 is reached, such as between about 100 Å and about 5000 Å. Suitable process time may be controlled between about 10 seconds and about 600 seconds.

At an optional operation 506, a second inorganic layer, so called an interface enhancement layer 603, may be formed on the first inorganic layer 602, as shown by the dotted lines in FIG. 6B. The interface enhancement layer 603 may be formed by a deposition process, similar to the deposition process depicted in operation 504, or a surface treatment process to convert a portion of the first inorganic layer 602 into the interface enhancement layer 603. In the example wherein the interface enhancement layer 603 is formed by a deposition process, the gas mixture utilized to form the interface enhancement layer 603 may include at least one silicon containing gas and an oxygen containing gas and a nitrogen containing gas when a silicon, oxygen and nitrogen containing layer is formed as the interface enhancement layer 603. Suitable examples of the silicon containing gas include SiH₄, Si₂H₆, SiCl₄ and the like. Suitable examples of the oxygen containing gas include O₂, N₂O, NO₂, O₃, H₂O, CO₂, CO, combinations thereof and the like. Suitable examples of the nitrogen containing gas include N₂, NH₃, N₂O, NO₂, combinations thereof and the like. Furthermore, other suitable carrier gas including inert gas (e.g., Ar, He, Ne, Kr or the like) or H₂ or N₂ gas may also supply in the gas mixture as needed.

The gas mixture supplied to deposit the interface enhancement layer 603 includes SiH₄, N₂, NO₂ and NH₃. It is believed that the silicon and oxygen elements from the interface enhancement layer 603 not only have silicon elements to form strong bonding with the silicon elements from the underlying first inorganic layer 602, but also include elements (e.g., oxygen elements) so as to provide similar film properties (e.g., compatible film characteristics) at the interface to improve surface adhesion and eliminate the likelihood of film peeling that may be caused by poor adhesion and/or incompatible film properties. Furthermore, the nitrogen elements as formed in the silicon, oxygen and nitrogen containing layer in the interface enhancement layer 603 may efficiently bridge with the first inorganic layer 602, thus providing a good surface adhesion at the both interfaces between the interface enhancement layer 603 and the first inorganic layer 602. In one embodiment, the interface enhancement layer 603 may be SiO₂, SiON or SiO_{X}N_{y}, wherein x and y are integers. In one particular embodiment, the interface enhancement layer 603 disposed on the first inorganic layer 602 is a silicon oxynitride layer (SiON).

In one particular embodiment, the interface enhancement layer 603 disposed on the first inorganic layer 602 is a silicon oxynitride layer (SiON). The gas mixture supplied to deposit the silicon oxynitride layer (SiON) includes SiH₄, N₂, NO₂ and NH₃. The SiH₄ gas supplied in the gas mixture is controlled at between about 4.0 sccm/L and about 15 sccm/L. N₂ gas is supplied to the gas mixture between about 44 sccm/L and about 66 sccm/L. NH₃ gas is supplied to the gas mixture between about 19 sccm/L and about 40 sccm/L. NO₂ gas supplied in the gas mixture is controlled at between about 11 sccm/L and about 22 sccm/L. The N₂ gas and NO₂ gas supplied in the gas mixture may be controlled at a flow ratio from about 1:1 to about 1:10, such as between about 1:2 and about 1:5, for example between about 1:1.5 and about 1:3.

Alternatively, the optional interface enhancement layer 603 at operation 506 may be obtained by performing a surface treatment process on the first inorganic layer 602 so as to form the interface enhancement layer 603 on the first inorganic layer 602. The surface treatment process plasma treats the first inorganic layer 602 disposed on the substrate 102 to alter the substrate surface properties. The plasma surface treatment process may efficiently incorporate certain elements to react with the unsaturated bonds in the first inorganic layer 602 so as to improve the bonding energy at the interface with the first inorganic layer 602 subsequently formed thereon. The surface treatment process may assist removing contaminants from the surface of the first inorganic layer 602, thereby providing a good contact interface between the first inorganic layer 602 as well as the layers subsequently formed thereon. Furthermore, the treatment process may also be performed to modify the morphology and/or surface roughness of the surface of the first inorganic layer 602 to improve the adhesion of the subsequently deposited interface enhancement layer 603, if present. In one embodiment, the surface treatment process may create a roughened surface having a surface roughness between about 6 Å and about 60 Å.

In one embodiment, the surface treatment process may be performed by supplying a gas mixture including an oxygen containing gas into the processing chamber. The oxygen containing gas may be selected from the group consisting of O₂, N₂O, NO₂, O₃, H₂O, CO₂, CO, combinations thereof and the like. In one exemplary embodiment, the oxygen containing gas used to perform the substrate treatment process includes O₂ gas. Furthermore, in certain embodiments, an inert gas may be used to perform the surface treatment process. The inert gas may not only assist removing containment from the surface of the first inorganic layer 602. Examples of the inert gas include Ar, He and the like. It is noted that the process parameters used to perform the surface treatment process by using the oxygen containing gas may be configured to be similar with the process parameters for using the inert gas.

During plasma surface treatment process, the substrate temperature is controlled less than about 100 degrees Celsius, such as between about 40 degrees Celsius and about 90 degrees Celsius, for example between about 60 degrees Celsius and about 90 degrees Celsius, or about 80 degrees Celsius. The lower temperature surface treatment process may prevent the organic materials disposed in or on the substrate 102 from being destroyed or damaged. The N₂ gas and NH₃ gas supplied in the gas mixture may be controlled at a flow ratio from about 10:1 to about 1:1, such as between about 5:1 and about 2:1, for example between about 3:1 to about 4:1.

Several process parameters may be controlled while performing the surface plasma treatment process. The gas flow for supplying the nitrogen containing gas is between about 0 sccm/L and about 55 sccm/L, such as between about 4 sccm/L and about 44 sccm/L, for example about 9 sccm/L and about 28 sccm/L. In the embodiment wherein N₂ gas and the NH₃ gas mixture is used to perform the surface treatment process, the N₂ gas and NH₃ gas supplied in the gas mixture may be controlled at a flow ratio from about 10:1 to about 1:1, such as between about 5:1 and about 2:1, for example between about 3:1 to about 4:1. The RF power supplied to perform the treatment process may be controlled at between about 0 milliWatts/cm² and about 1500 milliWatts/cm², such as about 200 milliWatts/cm² and about 700 milliWatts/cm², such as about 500 milliWatts/cm² for surface treatment process. The spacing may be controlled between about 800 mils and about 1000 mils. The process pressure may be controlled at between about 0.8 Torr and about 2 Torr. The process time may be controlled at a range between about 15 seconds and about 30 seconds.

At operation 508, after the first inorganic layer 602 and the optional interface enhancement layer 603 is formed on the substrate 102, the substrate 102 may be then transferred to a plasma treatment. In one example, the plasma treatment may be an electron beam (e.g., e-beam) treatment performed in an electron beam treatment chamber, such as the electron beam chamber 300, depicted in FIG. 3, to perform an electron beam treatment process on the substrate 102. The plasma treatment process, such as an electron beam treatment, at operation 508 forms a treated layer 604 on the first inorganic layer 602 or the optional interface enhancement layer 603, if present, as shown in FIG. 6C. In one embodiment, the treatment process may be performed in an electron beam treatment chamber, such as the electron beam chamber 300 depicted in FIGS. 3-4. In this particular embodiment, the deposition process at operation 504 and/or 506 and the electron beam treatment process at operation 508 are performed ex-situ respectively at a CVD chamber and an electron beam apparatus, such as the PECVD chamber 200 and the electron beam chamber 300 depicted in FIGS. 2-4. The CVD chamber and the electron beam apparatus may be incorporated in a cluster system so that the substrate being processed in between these two chambers does not expose to atmosphere or ambient environment and can be proceed under vacuum (e.g., without breaking vacuum).

In another embodiment, the treatment process may be performed in a CVD chamber equipped with an electron beam generating system, such as the electron beam generating system 450 disposed in the CVD processing chamber 200. In this particular embodiment, the electron beam treatment process may be performed in-situ where the first inorganic layer 602 and the optional interface enhancement layer 603 are formed at operation 504 and 506 without removing the substrate from the CVD processing chamber 200.

During the plasma treatment process, such as the electron beam treatment process at operation 508, an electron beam radiation is directed to the substrate 102 until a sufficient dose has accumulated to treat the first inorganic layer 602 or the optional interface enhancement layer 603, if present, and affect certain film properties, such as refractive index, solidity, moisture content, hardness, resistance to etchant chemical, e.g., wet or dry etching rate, and dielectric constant. A total energy dose of between about 10 micro-Coulombs per square centimeter (μC/cm²) and about 10,000 micro-Coulombs per square centimeter (μC/cm²) is treated to the first inorganic layer 602 or the optional interface enhancement layer 603. The electron beam is delivered at a high energy of between about 1000 volts and about 15000 volts to cathode 322. A bias energy to the anode 326 of between about 10 volts and about 100 volts is also delivered. The electron beam current ranges between about 1 mA and about 10 mA. The process pressure may be controlled between about 25 mTorr and about 75 mTorr. The substrate temperature is maintained at less than 100 degrees Celsius, such as between about 30 degrees Celsius and about 100 degrees Celsius, so as not to damage the organic materials formed in the OLED device structure 100 on the substrate 102.

The treatment gas that may be used includes inert gas treatment, oxygen gas treatment, ozone (O₃) gas treatment or the like. Suitable gases for the e-beam treatment process may include ozone (O₃), Ar, He, N₂, O₂, N₂O, H₂, NO₂ and the like. In an exemplary embodiment, the treatment gas as used is O₃, O₂ or N₂O gas. In one embodiment, the O₃ gas supplied during the treatment process is controlled at between about 25 sccm and about 250 sccm.

In one embodiment, the high energy and/or the bias energy as generated during the electron beam treatment process may be gradually tuned down or tuned up as needed to control treatment efficiency. In an exemplary embodiment, the high energy as applied during the electron beam treatment process may be tuned down while the bias energy may be tuned up. In at least one embodiment, the electron beam treatment process is a three operation process in which the high energy applied in each step (from the first operation to the third operation) is gradually tuned down while the bias energy applied in each step (from the first step to the third step) is gradually tuned up. In one example, in the first step of the electron beam treatment process, the high energy to the cathode 322 is controlled at between about 1000 volts and about 20000 volts, such as about 15000 volts while the bias energy to the anode 326 is controlled at between about 10 volts and about 100 volts, such as about 20 volts. The first step may be performed at a first time period between about 1 minutes and about 15 minutes. In the second step of the electron beam treatment process, the high energy is controlled at between about 1000 volts and about 15000 volts, such as about 6000 volts while the bias energy is controlled at between about 10 volts and about 100 volts, such as about 35 volts. The second step may be performed at a first time period between about 1 minute and about 15 minutes. In the third step of the electron beam treatment process, the high energy is controlled at between about 1000 volts and about 15000 volts, such as about 3000 volts while the bias energy is controlled at between about 10 volts and about 100 volts, such as about 45 volts. The third step may be performed at a first time period between about 1 minute and about 15 minutes.

After the plasma treatment process, it is believed that the treated layer 604 from the first inorganic layer 602 or the optional interface enhancement layer 603 may have an improved wettability as compared to conventional inorganic layer. The treatment process may densify the bonding structure of the first inorganic layer 602 or the optional interface enhancement layer 603, increasing the bonding energy of the silicon bonds and/or silicon-nitride bonds. As the bonding energy of the silicon bonds in the treated layer 604 is increased, the treated layer 604 becomes good interface property that may help bridging with the silicon or carbon elements from the layers subsequently formed thereon.

At operation 510, after the plasma treatment process, such as an e-beam treatment, at operation 508, an organic layer deposition process may then be performed to form an organic layer 605 on the treated layer 604, as shown in FIG. 6D. It is noted that the organic layer 605 may be similar to the organic layer 110 depicted in FIG. 1. The organic layer 605 may be a polymer material composed by hydrocarbon compounds. The organic layer 605 may have a formula CₓH_{y}O_{z}, wherein x, y and z are integers. In one particular embodiment, the organic layer 605 may be selected from a group consisting of polyacrylate, parylene, polyimides, polytetrafluoroethylene, copolymer of fluorinated ethylene propylene, perfluoroalkoxy copolymer resin, copolymer of ethylene and tetrafluoroethylene, parylene or other suitable polymeric materials. In one embodiment, the organic layer 605 is polyacrylate or parylene.

In one example, the organic layer 605 may be formed by an inkjet process, a spin-coating process, spray coating, aerosol coating, or other suitable deposition process as needed.

It is believed that the unsaturated carbon bonds in the organic layer 605 may efficiently adhere on to the treated layer 604 on the substrate surface, turning the unsaturated carbon bonds into saturated carbon bonds interfacing with the treated layer 604, creating a surface with strong bonding and adhesion. Furthermore, as discussed above, the silicon elements and/or oxygen elements (from the ozone e-beam treatment process) may also efficiently react with the carbon elements in the organic layer 605 to improve surface adhesion and integration and eliminate likelihood of film peeling that may be caused by poor adhesion and/or incompatible film properties.

After the organic layer 605 is formed on the substrate, a deposition may be performed, similar to the deposition process at operation 506 to optionally form an additional interface enhancement layer 608 on the organic layer 605, as shown in FIG. 6E, followed by a second inorganic layer 610 of operation 504, as shown in FIG. 6F, as indicated by the loop 512. In the example wherein the optional operation 506 is not performed, the additional interface enhancement layer 608 may be eliminated and the second inorganic layer 610 may be directed form on the organic layer 605.

After the interface integration and adhesion enhancement process 500 was performed by performing an ozone treatment process on an inorganic layer or an optional interface enhancement layer, no peeling, bubbles, or film cracks were found at the interfaces among the treated layer 604, first inorganic layer 602, the organic layer 605, the interface enhancement layer 603, demonstrating improved interface adhesion with little or no defects.

Thus, methods for enhancing interface management in an encapsulating structure in OLED applications are provided. The method includes forming a treated layer by an electron beam treatment process on an inorganic layer or interface enhancement layer followed by an organic layer that efficiently improves interface bonding energy, so that the interface adhesion and integration is enhanced. The electron beam treatment process as performed may assist incorporating desired elements to a desired depth of an organic or inorganic surface, thereby efficiently improving film adhesion and structure integration with good bonding energy, thus substantially eliminating likelihood of peeling or particle generation.

While the foregoing is directed to embodiments of the present disclosure, other and further embodiments of the disclosure may be devised without departing from the basic scope thereof, and the scope thereof is determined by the claims that follow.

1. A method of enhancing interface adhesion and integration in a film structure disposed on a substrate, comprising:
performing a plasma treatment process on an inorganic layer disposed on a substrate in a processing chamber to form a treated layer on the substrate, wherein the substrate includes an OLED structure, wherein the plasma treatment process in-situ generates a plasma in the processing chamber;
controlling a substrate temperature less than about 100 degrees Celsius during the in-situ plasma treatment process; and
forming an organic layer on the treated layer.

2. The method of claim 1, wherein the organic layer is selected from a group consisting of polyacrylate, parylene, polyimides, polytetrafluoroethylene, copolymer of fluorinated ethylene propylene, perfluoroalkoxy copolymer resin, copolymer of ethylene and tetrafluoroethylene, parylene.

3. The method of claim 1, wherein the inorganic layer is a silicon nitride layer or a silicon oxide layer.

4. The method of claim 1, further comprising:
forming an interface enhancement layer on the inorganic layer prior to forming the treated layer.

5. The method of claim 4, wherein the interface enhancement layer is an inorganic layer fabricated from silicon oxide, silicon nitride, or silicon oxynitride.

6. The method of claim 4, wherein the interface enhancement layer is a silicon oxynitride layer when the inorganic layer is a silicon nitride layer.

7. The method of claim 1, wherein the plasma treatment process further comprises:
supplying a gas mixture including an oxygen containing gas to treat the inorganic layer.

8. The method of claim 7, wherein the oxygen containing gas is ozone, O₂ or N₂O.

9. The method of claim 1, further comprising:
forming an interface enhancement layer on the organic layer.

10. The method of claim 9, wherein the interface enhancement layer is a silicon nitride layer or a silicon oxynitride layer.

11. The method of claim 9, further comprising:
forming an additional inorganic layer on the interface enhancement layer.

12. The method of claim 1, wherein the plasma treatment process includes an electron beam treatment process.

13-20. (canceled)

21. A method of enhancing interface adhesion and integration in a film structure disposed on a substrate, comprising:
performing an electron-beam plasma treatment process on an inorganic layer disposed on a substrate in a processing chamber to form an electron-beam treated layer on the substrate, wherein the substrate includes an OLED structure;
controlling a substrate temperature less than about 100 degrees Celsius while performing the electron-beam plasma treatment process; and
forming an organic layer on the electron-beam treated layer.
